(19) United States
(12) Patent Application Publication
(10) Pub. No.: US 2016/0327390 A1
(43) Pub. Date: Nov. 10, 2016

(54) METHOD AND APPARATUS FOR DECOUPLING ENVIRONMENTAL AND MODAL DEPENDENCIES IN INERTIAL MEASUREMENT DEVICES

(71) Applicant: QUALTRE, INC., Marlborough, MA (US)

(72) Inventors: Diego E. Serrano, Peachtree City, GA (US); Mohammad F. Zaman, Worcester, MA (US); Farrokh Ayazi, Atlanta, GA (US); Amir Rahafrooz, Providence, RI (US); Wang-Kyung Sung, Boston, MA (US); Ijaz Jafri, Holliston, MA (US)

(21) Appl. No.: 15/111,016

(22) PCT Filed: Jan. 13, 2015
(86) PCT No.: PCT/US15/11204

§ 371 Date: Jul. 12, 2016

Related U.S. Application Data
(60) Provisional application No. 61/926,625, filed on Jan. 13, 2014.

(51) Int. Cl. G01C 19/5698; H03H 9/02; H03H 3/02; H03H 9/17

(52) U.S. Cl. CPC G01C 19/5698; H03H 9/17; H03H 9/02007; H03H 3/02

(57) ABSTRACT

A resonant gyroscope apparatus has a decoupling mechanism implemented with spring-like flexure members to effectively isolate an axis-symmetric bulk-acoustic wave (BAW) vibratory gyroscope from its substrate, thereby minimizing the effect that external sources of error have on offset and scale-factor. The spring-like structure enables degeneracy of in-plane resonance modes of the annulus and aids in decoupling the in-plane and out-of-plane resonance modes of the resonant annulus, thereby enabling the mode-matched and/or near mode-matched operation of the structure as a vibratory gyroscope in the pitch, roll and yaw-modes. In various embodiments, the decoupling mechanism may be coupled to either an interior or exterior perimeter of an annulus shaped resonator element of the gyroscope

### FIELD OF THE INVENTION

The disclosure relates to resonant devices, and, more specifically, to resonant gyroscopes and inertial sensors.

### BACKGROUND OF THE INVENTION

Micro-machined vibratory gyroscopes are increasingly used in applications that require large dynamic range and large bandwidth such as gaming controllers and smart user interfaces. The popularity of such gyroscopes has grown, in large part, due to their low cost, small size, robustness and low power consumption, attributes which had been hardly achievable with conventional gyroscopes. One such gyroscopic device is disclosed in U.S. Pat. No. 7,543,496, entitled “Bulk Acoustical Wave Gyroscope,” the subject matter which is incorporated herein by this reference for all purposes.

Micro-machined gyroscopes have thus enabled a myriad of applications that range from basic motion detection for gaming, to safety control systems in automobiles. More recently, an increased interest in the use of MEMS inertial sensors for dead reckoning and pedestrian navigation in hand-held electronics has placed stringent requirements in die size, power consumption and overall performance of this type of devices. As of today, most commercially available rate sensors are designed as low-frequency flexural tuning-fork gyroscopes (TFGs), which are typically sensitive to random vibration and prone to linear acceleration (such as the one experienced under shock). These limitations complicate the use of TFG technology in large-volume high-end applications, particularly in personal navigation, where dependencies on fluctuations in the environment translate into long-term drift at the output of the system. Recently, concerns about the high sensitivity of consumer-grade gyroscopes to low-frequency pressure signals that can be used to recover audio have been raised as a potential threat for eavesdropping, justifying the need for more environmentally-robust rotation sensors.

Acceleration suppression mechanisms can be implemented in TFGs to alleviate part of this problem by utilizing redundant proof-masses that reject shock and vibration as common-mode signals. However, this compensation technique results in a significant increase in size, and could require electromechanical calibration to compensate for fabrication imperfections, making them more suitable in low-volume systems.

As an alternative, the degenerate modes of bulk-acoustic wave (BAW) resonators can be used to implement axis-symmetric mode-matched gyroscopes operating in the MHz range with high quality factors at moderate vacuum levels (1 to 10 Torr). Given their high-frequency nature, BAW gyros inherently reject the effects of random vibrations in the environment and are highly immune to shock.

However, like in any other type of gyroscope, differences in the loss mechanisms of the two degenerate modes can lead to damping coupling, which result in unwanted environment-dependent offset variations. In axis-symmetric gyros, fabrication or material imperfections can cause different support-loss rates for each of the modes, particularly if implemented in anisotropic substrates such as (100) single-crystal silicon (SCS).

Accordingly, a need exists for a gyroscope which minimizes environmental dependencies—such as temperature, shock and vibration—through the reduction of anchor-loss.

A further need exists for a simpler design of a resonant gyroscope which achieves the benefit of mode matching.

### SUMMARY OF THE INVENTION

According to one aspect of the disclosure, methods and structures are disclosed for the minimization of environmental dependencies in vibratory gyroscopes—such as temperature, shock and vibration—through the reduction of anchor-loss. This is achieved by effectively decoupling the resonant structure of the gyroscope from the substrate, which serves to isolate the structure from external unwanted stimuli, and reduces the environment-dependent discrepancies of the loss mechanisms of the two modes of the gyroscope. Discrepancies in the loss mechanisms of the modes leads to mode-to-mode coupling, which translates into bias at the output of the gyroscope. Thus, reducing differences between the modes is important.

According to one aspect of the disclosure, a new type of high-frequency, mode-matched gyroscope with significantly reduced dependencies on environmental stimuli, such as temperature, vibration and shock, is disclosed herein. A novel decoupling mechanism implemented with flexure members is utilized to effectively isolate an axis-symmetric bulk-acoustic wave (BAW) vibratory gyroscope from its substrate, thereby minimizing the effect that external sources of error have on offset and scale-factor. The disclosed high-frequency gyroscope may be used for z-axis rate detection and combines the properties of a BAW sensor with an isolation substrate-decoupling structure in order to significantly reduce anchor-loss in the system. Such substrate-decoupled (SD) BAW gyroscope attains highly improved environmental performance and offers the versatility necessary in high-volume production for consumer, automotive and industrial applications.

The disclosed substrate-decoupling structure is provided for suspending a resonant element of a gyroscope from it respective support structure. The configuration of the substrade-decoupling structure enables degeneracy of in-plane resonance modes of the annulus. The substrade-decoupling structure also aids in decoupling the in-plane and out-of-plane resonance modes of the annulus. Both these features enable the mode-matched and/or near mode-matched operation of the structure as a vibratory gyroscope in the pitch, roll and yaw-modes.

In one embodiment a substrate-decoupling configuration is constructed with a mirrored arrangement of a double-folded fish-hook spring. The first ends of the spring are connected radially along the perimeter wall of the resonant element. The other ends of the spring are connected to the the support structure. An appropriate distribution pattern of the springs may be used to tailor the frequency of the out-of-plane modes to be in close-proximity of the in-plane modes of the gyroscope.

According to an aspect of the disclosure, a resonant apparatus comprises: a resonant member; a structure for supporting the resonant member relative to another surface, and a decoupling mechanism for flexibly decoupling the resonant member from the support structure and substrate. In one embodiment, the resonant member is substantially annulus shaped and the structure for supporting the resonant member comprises an anchor. In one embodiment, the decoupling mechanism comprises a plurality of springs coupling a perimeter the resonant member to the supporting structure. In one embodiment, the decoupling mechanism enables degeneracy of in-plane resonance modes of the resonant member.

According to another aspect of the disclosure, a gyroscope apparatus comprises: a substantially annulus shaped resonator element having a pattern of flexure members extending outward therefrom; and a structure for supporting the resonant member relative to a another surface, and wherein each flexure member has a plurality of substantially right angle transitions between first and second ends thereof.

According to another aspect of the disclosure, a method of manufacturing a bulk acoustic wave resonator element comprises: A) forming an annulus shaped resonator element having a perimeter edge; B) etching a plurality of apertures in the resonator element to collectively define a plurality of springs extending from the perimeter edge, wherein the springs each of the springs comprises a flexure member having a plurality of substantially right angle transitions.

According to yet another aspect of the disclosure An article of manufacture comprising an annulus shaped resonator element separated from a support structure by a plurality of springs connecting, wherein each of the springs comprises a flexure member having a plurality of substantially right angle transitions between junctures with the annulus shaped resonator element and support structure.

### BRIEF DESCRIPTION OF THE DRAWINGS

The present disclosure will be more completely understood through the following description, which should be read in conjunction with the drawings in which:

FIG. 1 illustrates conceptually a schematic representation of a rotation-rate gyroscope in accordance with the disclosure;

FIG. 2 illustrates conceptually a schematic representation of a gyroscope with stiffness and damping imperfections and how a drive force generates an unwanted ZRO displacement in accordance with the disclosure;

FIGS. 3A-C illustrates conceptually graphs of the frequency responses of a BAW disk gyroscope in accordance with the disclosure;

FIGS. 4A-B illustrate conceptually perspective and cross-sectional views, respectively, of a prior art uncoupled resonant capacitive BAW gyroscope implemented in (100) single-crystal silicon;

FIG. 5A illustrates conceptually a perspective view of a decoupled resonant capacitive BAW gyroscope in accordance with the disclosure;

FIG. 5B illustrates conceptually a cross-sectional view of the decoupled resonant capacitive BAW gyroscope of FIG. 7A in accordance with the disclosure;

FIG. 6 illustrates conceptually a top view of circular annulus suspended from an anchor by a substrate decuopling mechanism in accordance with the disclosure;

FIG. 7 illustrates conceptually a close up view of a the spring design-pair for decoupling a resonant member in accordance with the disclosure;

FIG. 8 illustrates conceptually a top view of circular annulus suspended from an anchor by radial arrangement of two dozen of the spring-pairs of FIG. 7 in accordance with the disclosure;

FIG. 9 illustrates conceptually a close-up view of the displacement of the spring decoupling mechanisms of FIGS. 8-8 during a simulation of an in-plane resonance mode of circular annulus in accordance with the disclosure;

FIG. 10 illustrates conceptually a close-up view of the displacement of the spring decoupling mechanisms of FIGS. 8A-C during a simulation of an out-of-plane resonance mode of circular annulus in accordance with the disclosure;

FIGS. 11A-D illustrate conceptually cross-sectional views of the process flow for the implementation of the disclosed SD-BAW Z-axis gyroscopes;

FIGS. 12A-I illustrate conceptually top views of different embodiments of mechanism for decoupling an annulus shaped resonant element suspended from an anchor support structure in accordance with the disclosure;

FIG. 13 illustrates conceptually a top view of a decoupled resonant capacitive BAW gyroscope in accordance with the disclosure;

FIG. 14 illustrates conceptually a top view of the decoupled resonant capacitive BAW gyroscope of FIG. 13 in conjunction with electrodes in accordance with the disclosure; and

FIGS. 15A-C illustrate conceptually top views of different embodiments of mechanisms for decoupling an annulus shaped resonant element suspended from a support structure in accordance with the disclosure.

### DETAILED DESCRIPTION

As used herein, the term “annulus” is intended to mean any geometric shape defined by an exterior perimeter surface and an interior perimeter surface which defines an aperture or opening at the center of the geometric shape, such annulus not be being just limited to circular in shape but having exterior and interior perimeter profiles which may be any of circular, oval, or polygonal, in any combinations, as illustrated in the Figures or their equivalents thereto.

Prior to a description of the disclosed decoupling mechanisms the theoretical basis and equations of motion of ideal vibratory gyroscopes is discussed.

A gyroscope can be modeled as two separate and orthogonal second-order systems that are coupled by means of a force determined by the Coriolis effect and thus is proportional to the rotation-rate Ω(t):

$$\begin{matrix}{m}_{11} {\ddot{q}}_{1} ( t ) + {b}_{11} {\dot{q}}_{1} ( t ) + {k}_{11} {q}_{1} ( t ) = {\sum }_{i = 1}^{k} {f}_{1 , i} - 2 λ {m}_{22} Ω ( t ) {\dot{q}}_{2} ( t ) & ( 1 a ) \\ {m}_{22} {\ddot{q}}_{2} ( t ) + {b}_{22} {\dot{q}}_{2} ( t ) + {k}_{22} {q}_{2} ( t ) = {\sum }_{j = 1}^{l} {f}_{2 , j} + 2 λ {m}_{11} Ω ( t ) {\dot{q}}_{1} ( t ) . & ( 1 b )\end{matrix}$$

In equations (1a) and (1b) mₓₓ, bₓₓ and kₓₓ correspond to the mass, damping coefficient and spring constant, respectively, of the two systems, with x being the mode-pair number (either 1 or 2). The term λ is the angular gain dictated by the Bryan effect, and Ω(t) is the magnitude of the rate of rotation applied to the gyroscope device about an axis normal to the plane of vibration where the displacements of the two modes, q₁(t) and q₂(t), take place. The factors f_{1,i} and f_{2,j} are any additional forces applied to the first or second mode, respectively, in order to excite or control the gyroscope. Terms for the angular and centrifugal acceleration (∂Ω(t)/∂t and Ω²(t)) have not been considered because their effects on the system response are usually small enough to be neglected.

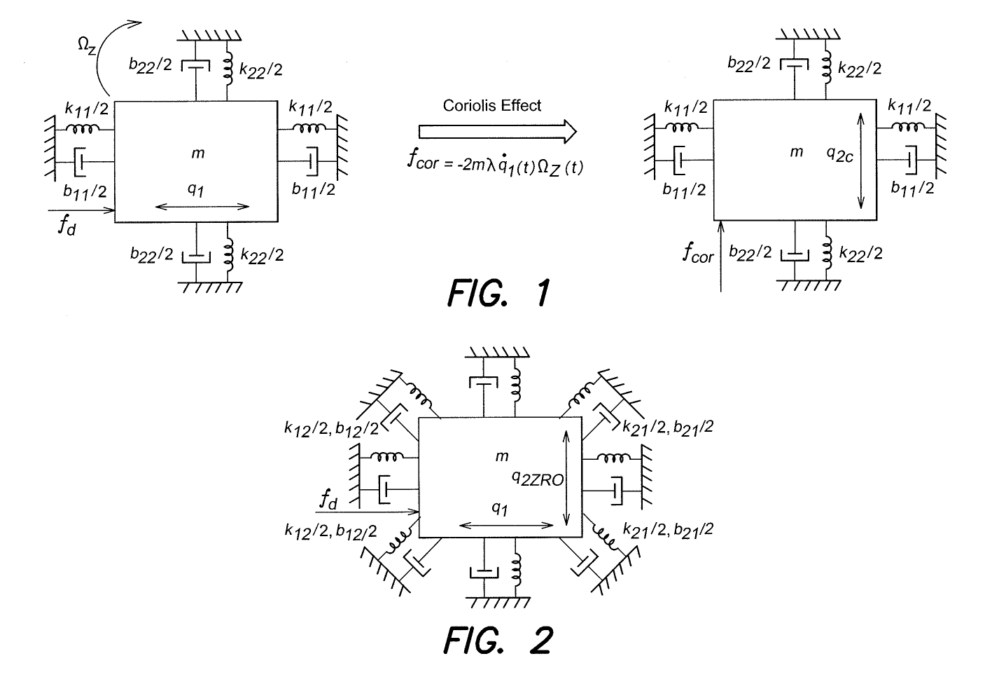

Vibratory gyroscopes can be configured to detect either (1) the angular velocity of a structure, or (2) the angle by which the structure has turned. Devices that detect angular velocity are commonly known as rotation-rate gyroscopes. In this type of gyros, one of the two modes, usually known as the drive-mode, is constantly excited into oscillation; the second mode, known as the sense mode, is used to detect the Coriolis force, which is proportional to the rate of rotation. FIG. 1 is a schematic representation of a rotation-rate vibratory gyroscope where the drive and sense modes are only coupled to each other by the force generated through the Coriolis effect. The masses m₁₁ and m₂₂ are assumed to be equal to m.

To achieve maximum transfer of energy between the drive and the sense modes when rotation is applied, the natural frequencies the two modes—given by equation (2a)—are generally designed to be equal. If fabrication imperfections cause the frequencies to differ from each other, electrostatic spring softening can be utilized, to some extent to match them. The loss of energy in each resonator is generally quantified in terms of their quality factor, which can be expressed in terms of the lumped-element parameters of the systems as shown in Equation (2b).

$$\begin{matrix}{ω}_{{0}_{x}} = \sqrt{\frac{{k}_{xx}}{{m}_{xx}}} & ( 2 a ) \\ {Q}_{x} = \frac{{ω}_{{0}_{xx}} {m}_{xx}}{{b}_{xx}} . & ( 2 b )\end{matrix}$$

For a frequency-matched (ω₀₂=ω₀₁) rotation-rate gyroscope, the sense-mode displacement can be found by solving equations (1a) and (1b) in the frequency domain under the assumption that the Coriolis force does not affect the drive-mode. This is usually a fair assumption given that control electronics can be used to regulate the drive signal. The ratio of sense-to-drive displacement under these conditions is given by:

$$\begin{matrix}{\vert \frac{{q}_{2 c}}{{q}_{1}} \vert}_{{ω}_{01} = {ω}_{02}} = \frac{2 λ {Q}_{2}}{{ω}_{{0}_{1}}} \overline{Ω} & ( 3 a ) \\ {∠ \frac{{q}_{2 c}}{{q}_{1}} \vert}_{{ω}_{01} = {ω}_{02}} = 0 ° . & ( 3 b )\end{matrix}$$

In expressions (3a) and (3a) it is also assumed that the frequency of the time-dependent input rotation-rate Ω(t), is much smaller than the resonance frequency of the structure so that it can be treated as a quasi-static variable.

### Mode-to-Mode Coupling in Vibratory Gyroscopes

Errors encountered during fabrication can cause not only small frequency splits between the two modes of vibration, but also cross-coupling between them. In rotation-rate gyros, these non-idealities produce an undesired excitation of the sense mode that will show up at the output even when no rotation-rate is applied, the resulting signal being commonly known as zero-rate output (ZRO).

The cross-excitation between the drive and sense modes can be modeled by adding stiffness-coupling and damping-coupling terms to the gyroscope lumped-element model described by equations (1a) and (1b):

$$\begin{matrix}{m}_{11} {\ddot{q}}_{1} ( t ) + {b}_{11} {\dot{q}}_{1} ( t ) + {b}_{12} {\dot{q}}_{2} ( t ) + {k}_{11} {q}_{1} ( t ) + {k}_{12} {q}_{2} ( t ) = {\sum }_{i = 1}^{k} {f}_{1 , i} - 2 λ {m}_{22} Ω ( t ) {\dot{q}}_{2} ( t ) & ( 3 a ) \\ {m}_{22} {\ddot{q}}_{2} ( t ) + {b}_{22} {\dot{q}}_{2} ( t ) + {b}_{21} {\dot{q}}_{1} ( t ) + {k}_{22} {q}_{2} ( t ) {k}_{21} {q}_{1} ( t ) = {\sum }_{j = 1}^{l} {f}_{2 , j} + 2 λ {m}_{11} Ω ( t ) {\dot{q}}_{1} ( t ) . & ( 3 b )\end{matrix}$$

The coupling terms represented by the constants k₂₁ and b₂₁, are force generators that cause a displacement excitation of the sense mode q_{2ZRO}(t)=q₂ₖ(t)+q_{2b}(t), even in the absence of rotation rate. FIG. 2 is a schematic representation of gyroscope including stiffness and damping coupling terms. A displacement in the sense-mode q_{2ZRO} is generated in even in the absence of rotation rate.

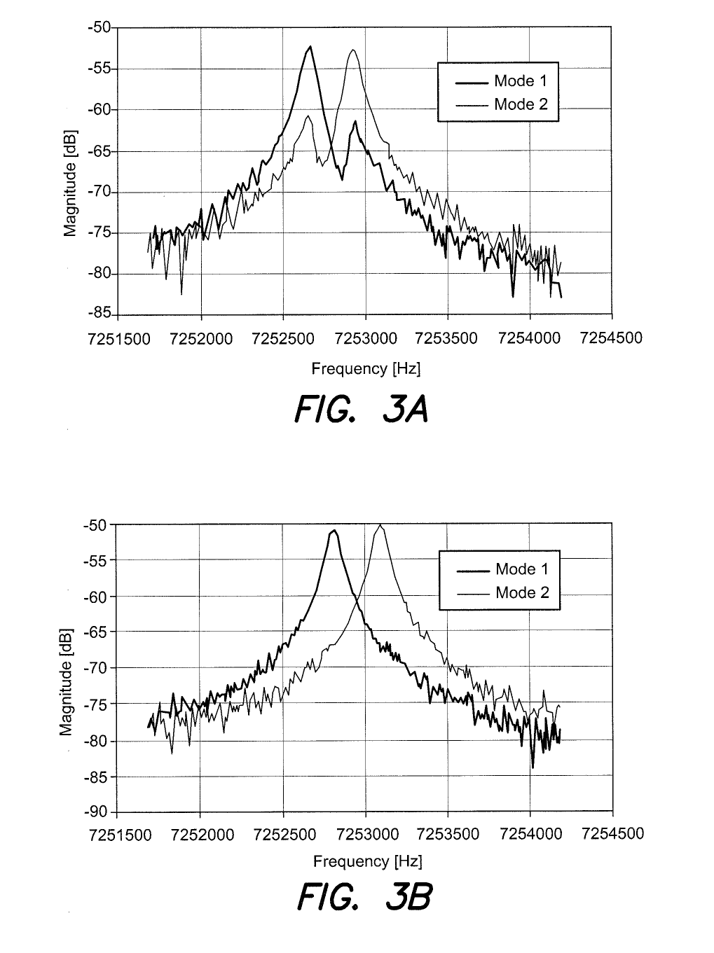

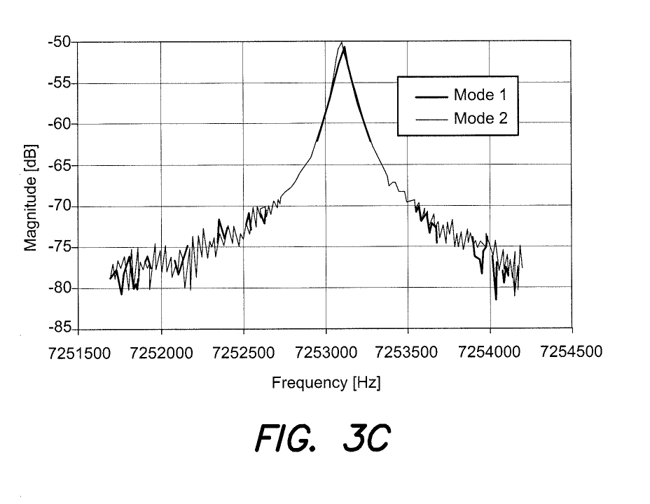

In equation (3b), the stiffness-coupling term k₂₁ generates a force that is proportional to the drive displacement q₁(t), whereas the rotation-rate force is a function of the drive velocity \dot{q}₁(t). This difference indicates that the ZRO signal q₂ₖ(t), generated by stiffness coupling, is 90° off with respect output displacement q_{2c}(t) generated by rate. Having q₂ₖ(t) always in quadrature with respect to the signal of interest facilitates its rejection by the use of I-Q demodulation in the sense electronics. Additionally, stiffness coupling can be effectively cancelled by the use of electrostatic forces similar to the ones used to mode-match the part. For instance, FIGS. 3A-C show the frequency response of the second elliptical modes of a BAW disk gyroscope before compensation, after electrostatic mode decoupling, and after electrostatic mode tuning, respectively. The as-born behavior of the device shows both a frequency split and a mode-to-mode stiffness coupling due to small fabrication imperfections, as shown in FIG. 3A. By the use of electrostatic forces located in between the antinodes of the two modes, the stiffness coupling terms of the device can be cancelled out, as shown in FIG. 3B. Similarly, by the use of forces aligned with the antinodes of one of the two modes, the frequency split can be brought down to zero, restoring the degeneracy of the device, as shown in FIG. 3C.

Unlike stiffness coupling, the damping-coupling force—generated by b₂₁—is proportional to the drive velocity \dot{q}₁(t), causing the signal q_{2b}(t) to have the same phase with respect to q_{2c}(t). This means that ZRO generated by b₂₁ are undistinguishable from displacements generated by rate, causing bias at the gyroscope output.

Sources of Damping Coupling

The damping ratio of a second-order system is a measure of the amount of energy lost per oscillation cycle. Asymmetries in the loss mechanisms of vibratory gyroscopes can lead to situations in which the damping coefficients of the resonance modes differ from each other, i.e. b₁≠b₂. If the resonance frequencies of the two modes are equal, one of the resonators will lose energy faster than the other. This difference can be represented as energy being transferred from one mode to the other, causing damping coupling. In other words, the damping coupling term b₂₁ can be expressed in terms of the the difference between the individual damping terms of each mode:

b₂₁∝b₂−bᵢ (4)

Keeping in mind that the quality factor is inversely proportional to the damping coefficient (equation (2b)), the total energy lost in a resonator can be expressed as a function of the different loss mechanisms in the system, as shown in Equation 5:

$$\frac{1}{{Q}_{TOTAL}} = \frac{1}{{Q}_{viscous}} + \frac{1}{{Q}_{TED}} + \frac{1}{{Q}_{surface}} + \frac{1}{{Q}_{material}} + \frac{1}{{Q}_{anchor}} \qquad ( 5 )$$

The first term on the left side of expression (4), Q_{viscous}⁻¹, corresponds to losses associated with viscous damping caused by the interaction between the resonator and the gas surrounding the structure. By operating at high vacuum levels, these losses can be significantly minimized. The second term (Q_{TED}⁻¹) is the energy lost because of the interaction of the mechanical resonances with the thermal modes of the structure; the mechanical and thermal domains are coupled to each other through the coefficient of thermal expansion (CTE) leading to thermoelastic damping (TED). For the case of degenerate modes of axis-symmetric gyroscopes, the value of TED for both modes is almost identical because the structure is perfectly symmetric. This leads to minimum TED coupling between the modes. In the case of TFG-like devices, the flexures should be properly designed to match the loss mechanisms. The factor Q_{surface}⁻¹ is related to scattering losses due to roughness in the device surface. This effect is minimized through fabrication processing steps to avoid major asymmetric contributions to the system losses. The next parameter (Qₘₐₜₑᵣᵢₐₗ⁻¹) is associated with other intrinsic losses of the material, such as phonon-phonon interactions, phonon-electron interactions, defects, impurities, dislocations, etc. These losses are typically low, particularly in the case of materials such as single-crystal silicon. The last term (Q_{anchor}⁻¹) corresponds to the energy dissipated from the resonator through its anchor point. Larger anchor dissipation also translates into higher coupling between resonating structure and the substrate. Thus, in gyroscopes with high anchor losses, environmental stimuli coming from the substrate will couple into the system causing an unwanted response. Furthermore, if the changes between the drive and sense modes are asymmetric, i.e., Q_{1-anchor}⁻¹ and Q_{2-anchor}⁻¹ vary differently, the gyroscope will experience environment-dependent damping coupling.

Bulk-Acoustic Wave Disk Gyroscopes

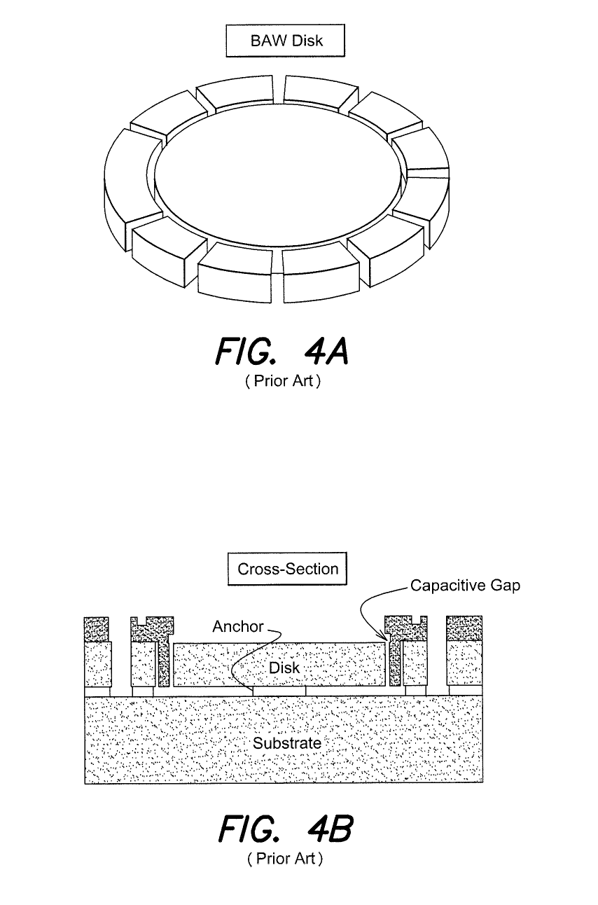

Bulk-acoustic wave (BAW) disk gyroscopes are a particular type of axis-symmetric gyros that use the high-frequency/high-Q degenerate modes of a micromechanical disk to detect rotation. BAW gyros are advantageous compared with low-frequency flexural structures because they provide higher open-loop bandwidth (for the same amount of Q) and are more robust to shock and vibration. FIG. 4 shows a schematic representation of a capacitive BAW disk resonator and its cross section when implemented in a (100) single crystal silicon (SCS) wafer. Ultra-narrow capacitive gaps are used as transducers to obtain high electromechanical coupling coefficients.

Second elliptical modes, i.e., the n=3 modes, may used for rate detection in an uncoupled BAW disk gyroscope implemented in (100) SCS. The first elliptical modes (n=2) can be used for devices implemented in isotropic materials, however for (100) SCS—which is an anisotropic substrate—this mode-pair is not degenerate, i.e., the frequencies of the two modes are not equal, hence the n=3 modes are used.

As can be seen in FIG. 4B, the uncoupled BAW disk is anchored to the substrate right at the center where the radial displacement is minimum for both modes. However, because of the anisotropic properties of (100) SCS, the n=3 modes experience an effective translation right at the center of the structure, causing shear stress in the substrate.

The anchor loss in a BAW resonator can be quantified by taking the ratio of the energy lost from the vibrating structure into the substrate, with respect to the energy stored in the device, as illustrated in Equation 6:

$${Q}_{anchor}^{- 1} = \frac{1}{2 π} \frac{Δ W}{W} , \qquad ( 6 )$$

where W represents the energy stored, and ΔW is the energy lost, which is a function of the stress and strain exerted by the anchor onto the substrate, as illustrated in Equation 7:

ΔW=π∫_{suport region}stress×displacement. (7)

In accordance Equation 7, a (100) SCS BAW disk anchored at the center will experience relatively high anchor-loss, causing the device to be tightly coupled to the substrate. Furthermore, since the direction of the shear stress for each mode is different, the effects of temperature and vibration will differ causing environment-dependent damping coupling.

Substrate-Decoupled BAW Gyroscopes

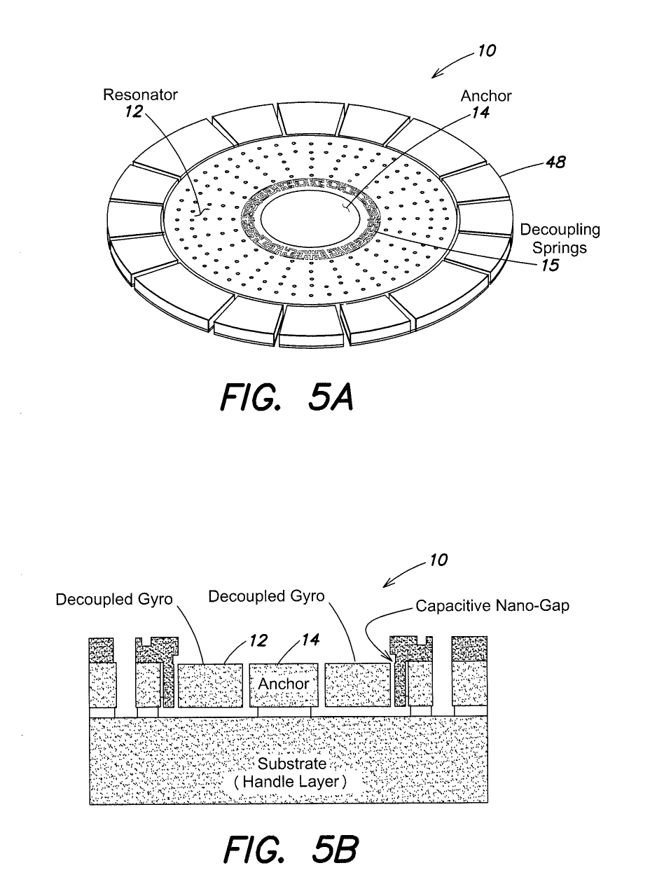

FIGS. 5A and 5B illustrate conceptually perspective and cross-sectional views, respectively, of a decoupled resonant capacitive BAW gyroscope 10 comprising a decoupling mechanism 15 implemented with spring-like flexure members to effectively isolate and suspend a circular/oval shaped resonant element 12 of gyroscope 10 from it respective support structure, which, in the illustrative embodiment, is a central anchor 14. In one embodiment, decoupling mechanism 15 comprises a plurality of spring like structures 20, each comprising a plurality of flexure member 22 mechanically coupled to both the resonant element 12 and support structure 14. The decoupling mechanism 15 enables degeneracy of in-plane resonance modes of the resonant element 12 facilitating mode-matched and/or near mode-matched operation of the structure as a vibratory gyroscope in the pitch, roll and yaw-modes.

In one embodiment, in order to minimize the transfer of energy between the gyroscope and the substrate, a plurality of spring pairs 20A-B, each comprising a plurality of flexure members 22, are placed in between the core resonating structure 12 and its anchor point. The design of flexure members 22 effectively prevents the transfer of strain-energy to the resonator/substrate interface. The placement and design of the decoupling mechanism 15 may vary by designer's choice as long as the strain-energy is effectively contained within the resonating device. Having lower anchor losses also leads to smaller values of damping coupling, i.e., the energy transferred from one mode to the other is lower because the overall energy lost is reduced.

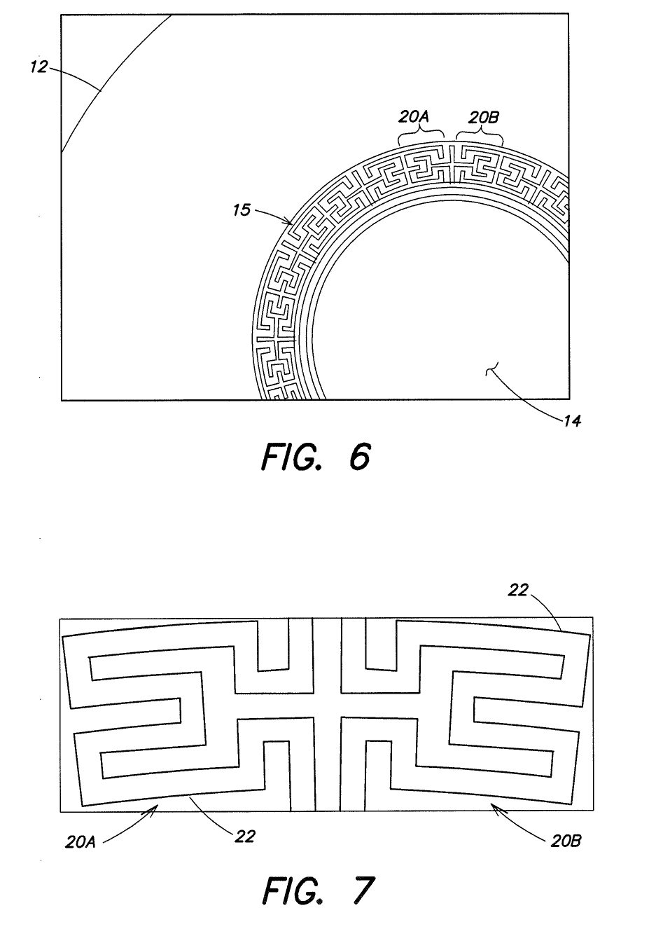

FIG. 6 illustrates conceptually a top view of resonant element 12 of gyroscope 10 suspended from a support structure 14 by a decoupling mechanism 15 comprising a radial arrangement of spring-pairs 20A-B. FIG. 7 illustrates conceptually a close up view of a spring-pair 20A-B constructed with a mirrored arrangement of a double-folded fish-hook shaped flexures 22. First ends of the springs are typically connected radially along a perimeter wall of the resonant element 12. Second ends of the springs are connected to the support structure 14, which, in the illustrative embodiment, is the central anchor. Each flexure member 22 is characterized by at least on abrupt angular transition, typically a right angle, between the points at which the flexure is coupled to either resonant element 12 or support structure 14. As illustrated in FIG. 7, in the illustrative embodiment, each flexure member 22 has multiple right angle transitions between the points or junctures at which it is coupled to either resonant element 12 or support structure 14. In embodiments, flexure member 22 may have the same or different thickness than either resonant element 12 or support structure 14.

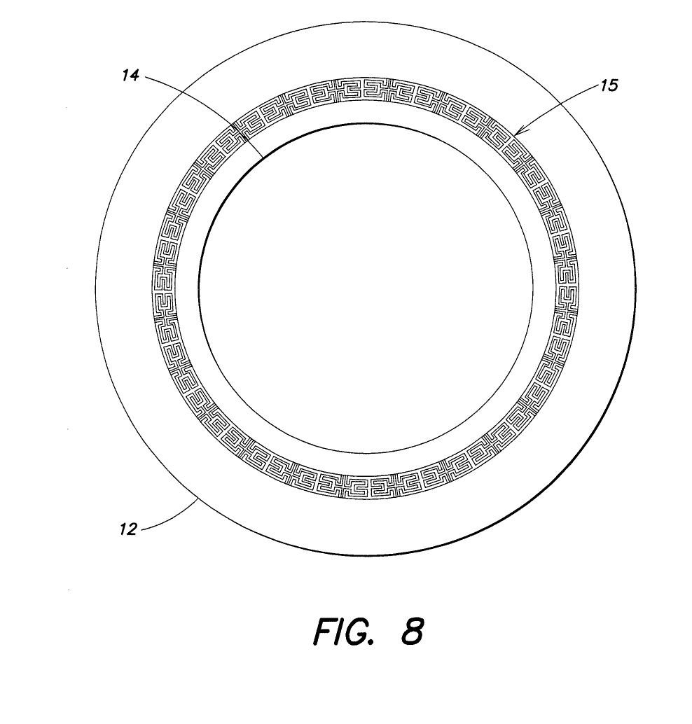

An appropriate distribution pattern of the springs 20 is used in decoupling mechanism 15 to tailor the frequency of the out-of-plane modes to be in close-proximity of the in-plane modes. FIG. 8 illustrates conceptually a top view of the entire circular annulus of resonant element 12 suspended from support structure 14 by radial arrangement of two dozen spring-pairs 20A-B. The disclosed spring design has the ability for the utilization as both a mode-matched yaw-gyroscope and a mode-matched pitch/roll gyroscope using a combination of out-of-plane and in-plane resonance modes of the annulus.

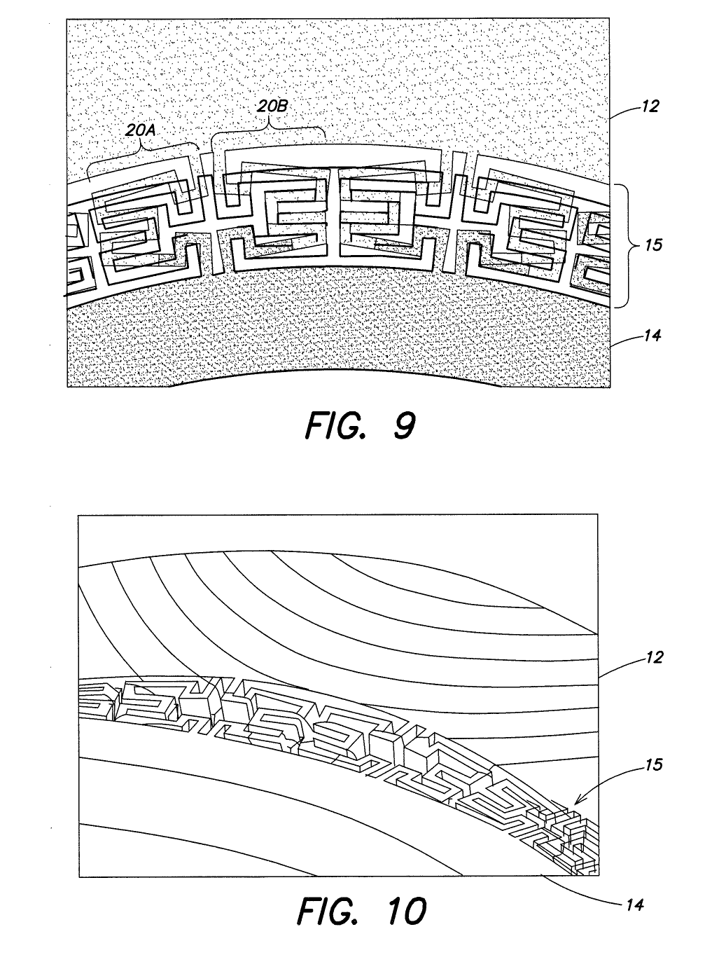

FIG. 9 illustrates conceptually a close-up view of the displacement of the springs 20 of FIG. 7 during a simulation of an in-plane resonance mode of the circular annulus which serves as resonant element 12. FIG. 10 illustrates conceptually a close-up view of the displacement of the springs 20 of FIGS. 7-8 during a simulation of an out-of-plane resonance mode of circular annulus which serves as resonant element 12.

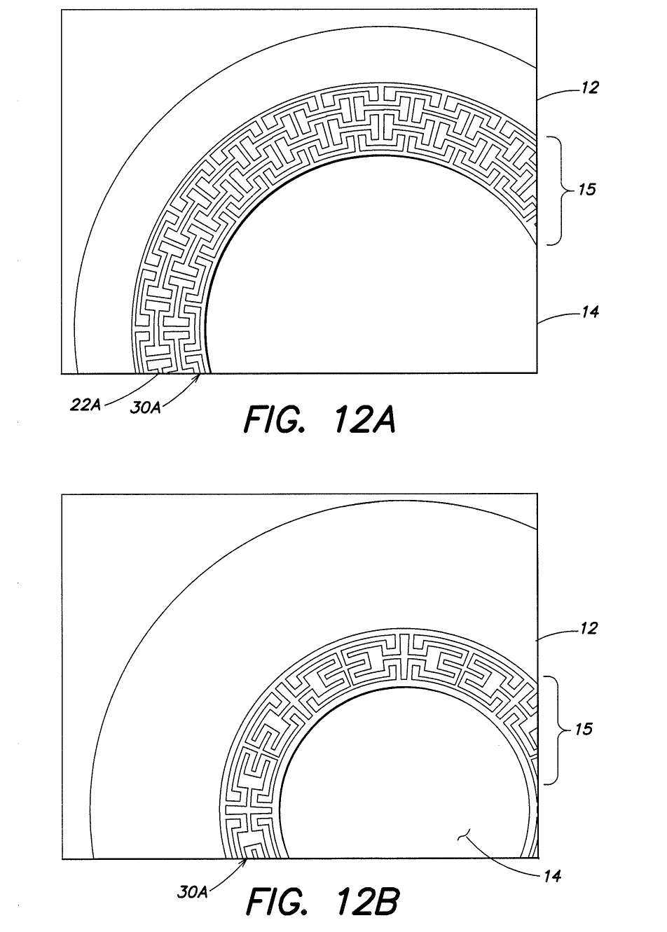

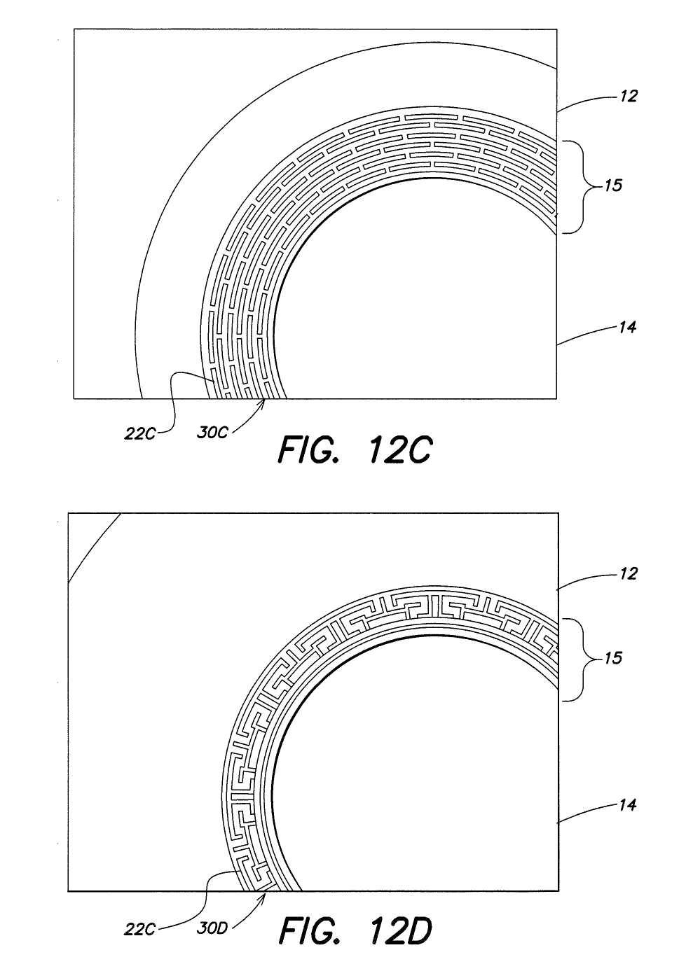

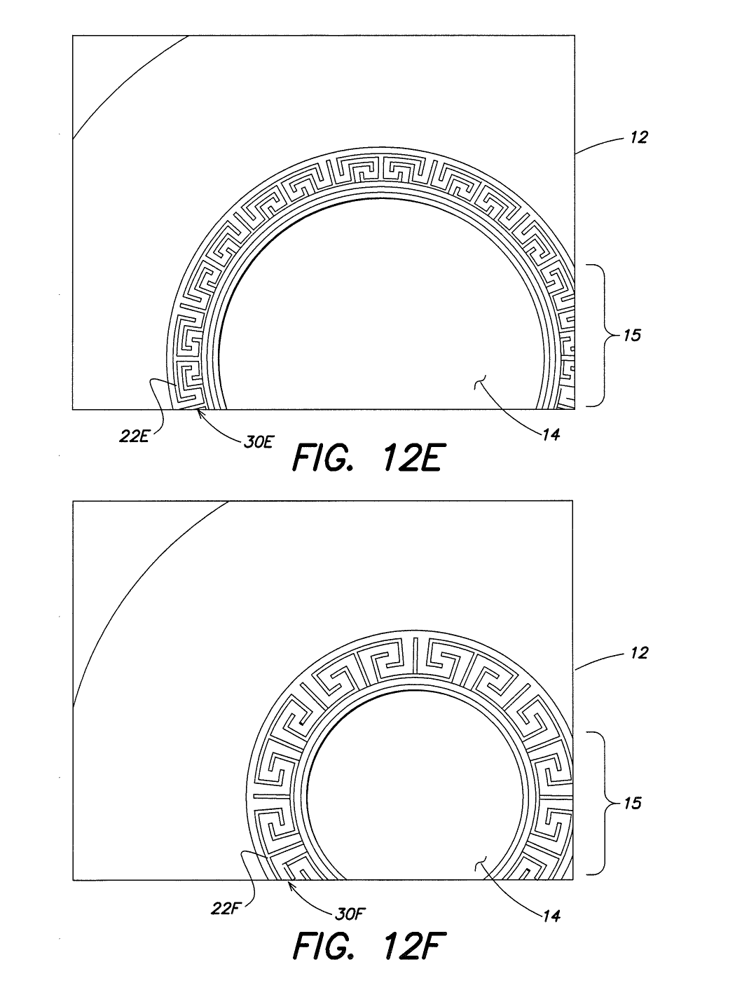

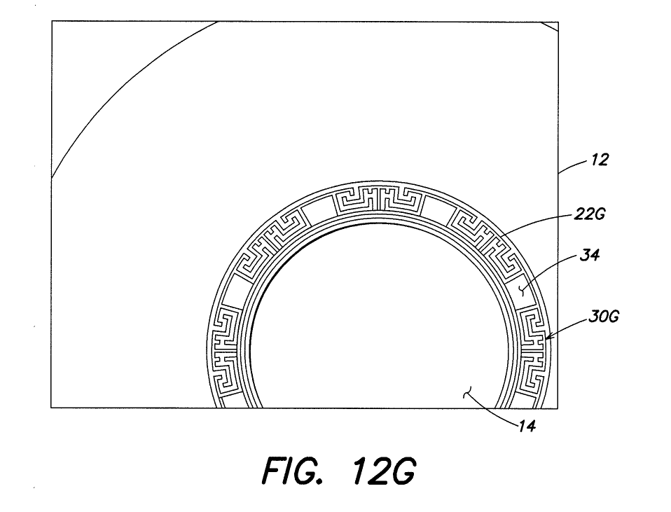

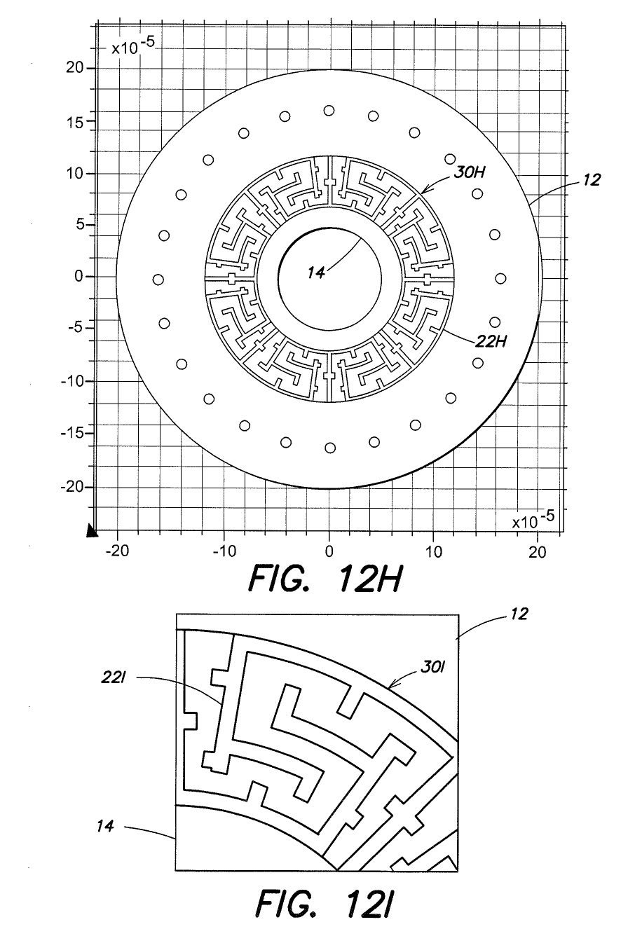

The configurations of the decoupling mechanism illustrated in FIGS. 6-8, as well as in FIGS. 12A-I, enable a number of features that are useful in operation of a circular/ovaled annulus as the resonant element of a vibratory gyroscope. In the yaw-mode (Z-Axis) configuration, an appropriate arrangement of the springs facilitates maintaining minimum frequency split between two in-plane resonance-modes of the annulus. In the pitch/roll mode (X-Y-Axis) configuration, an appropriate arrangement of springs enables maintaining minimum frequency split between the two out-of-plane resonance-modes and the in-plane resonance mode of the annulus without significant mode-coupling. In addition, the spring dimensions or/and arrangement between the resonator and the anchor may be used for tailoring the Quality Factor (Q) of the resonance modes, the resonance frequencies, and to enable frequency isolation of spurious/non-operational modes from the gyroscope modes of the annulus.

FIGS. 12A-I illustrate conceptually top views of additional embodiments of mechanism for decoupling the resonant element 12 from the support structure 14. The geometry and dimensions and number of the springs 30 may be designed in order to effectively reduce the amount of energy transferred between the resonator and the anchor/substrate and to cause the frequency of the out-of-plane modes of resonance to be in close-proximity to the frequency of the in-plane modes of resonance.

FIGS. 12A and 12C illustrate conceptually top views of embodiments in which the decoupling mechanism 15 comprises a plurality of springs 30A and 30C, respectively, in which each flexure member 22A and 22C, respectively, is characterized by twelve right angle transitions between the points at which the flexure member is coupled to either resonant element 12 or support structure 14.

FIG. 12B illustrates conceptually a top view of an embodiment in which the decoupling mechanism 15 comprises a plurality of spring-pairs 30A similar to those illustrated in FIGS. 8A-B but with less pairs than illustrated in FIG. 8.

FIG. 12D illustrates conceptually a top view of an embodiment in which the decoupling mechanism 15 comprises a plurality of springs 30D, each having a flexure member 22D characterized by at least six right angle transitions between the points at which the flexure member is coupled to either resonant element 12 or support structure 14, symmetrically arranged about projections 32 extending outwardly from support structure 14. In the illustrative embodiment springs 30D may be arranged adjacently in mirrored, i.e. symmetrically reflected, pairs.

FIG. 12E illustrates conceptually a top view of an embodiment in which the decoupling mechanism 15 comprises a plurality of springs 30E, each having flexure member 22E characterized by eight right angle transitions between the points at which the flexure member is coupled to either resonant element 12 or support structure 14. In the illustrative embodiment springs 30E may be arranged adjacently in mirrored pairs.

FIG. 12F illustrates conceptually a top view of an embodiment in which the decoupling mechanism 15 comprises a plurality of springs 30F each having a flexure member 22F characterized by six right angle transitions between the points at which the flexure member is coupled to either resonant element 12 or support structure 14. In the illustrative embodiment springs 30F may be arranged adjacently in mirrored pairs.

FIG. 12G illustrates conceptually a top view of an embodiment in which the decoupling mechanism 15 comprises a plurality of springs 30G, each having a flexure member 22G characterized by at least eight right angle transitions between the points at which the flexure member is coupled to either resonant element 12 or support structure 14 are alternatingly arranged with projections 34 extending outwardly from support structure 14. In the illustrative embodiment springs 30G may be arranged adjacently in mirrored, i.e. symmetrically reflected, pairs.

FIGS. 12H and 12I illustrates conceptually a top views of an embodiment in which the decoupling mechanism 15 comprises a plurality of springs 30H each having a flexure member 22H characterized by fourteen right angle transitions between the points at which the flexure member is coupled to either resonant element 12 or support structure 14. In the illustrative embodiment springs 30H may be arranged adjacently in mirrored pairs about the perimeter of resonant element 12.

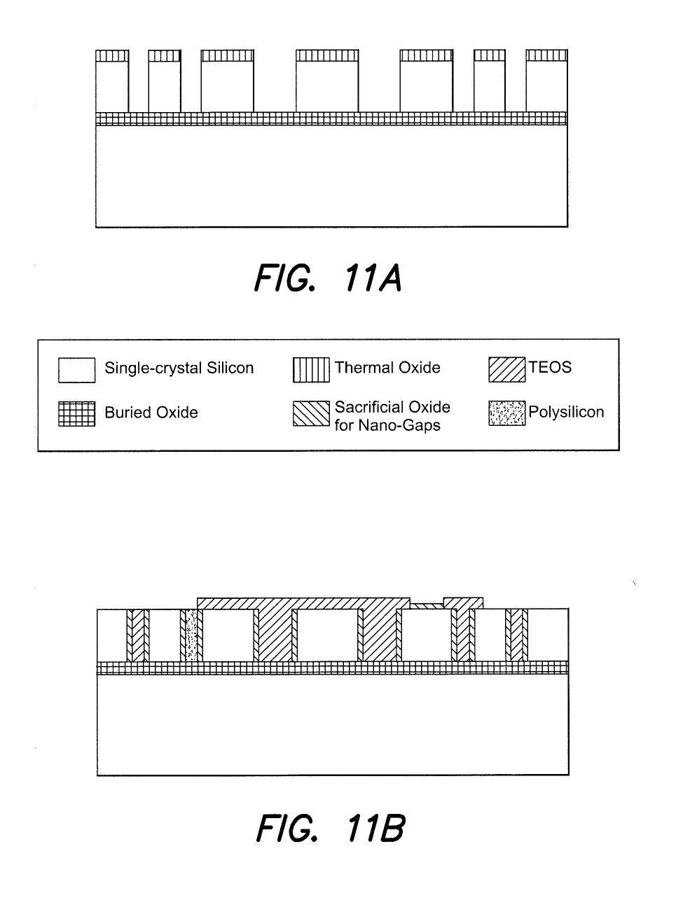

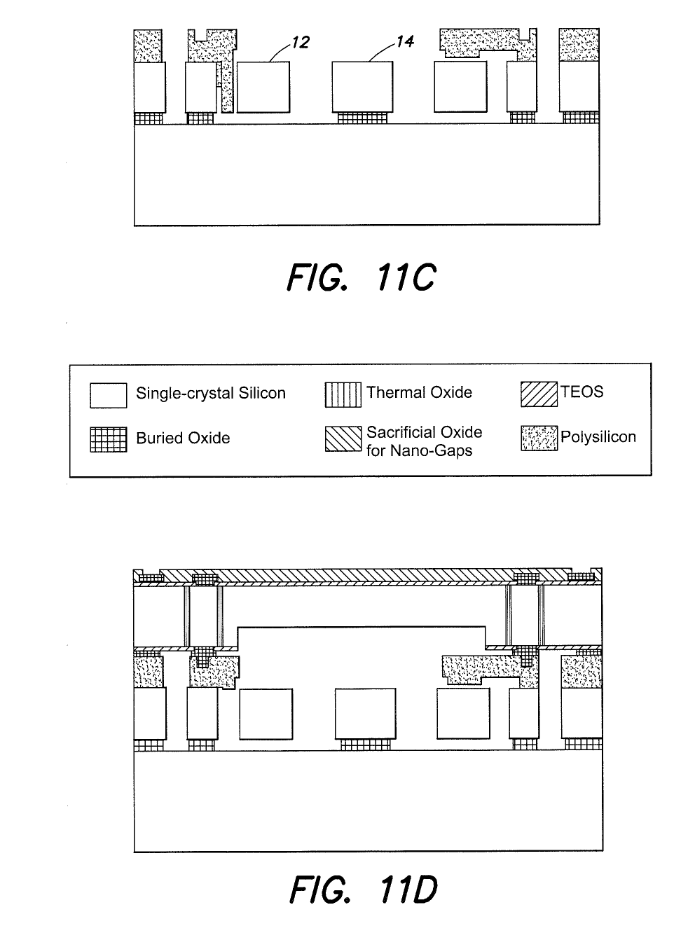

FIGS. 11A-D illustrate conceptually the process flow for the implementation of the disclosed SD-BAW Z-axis gyroscopes. The disclosed device may be implemented using a modified version of the high-aspect ratio poly- and single-crystal silicon (HARPSS™) process flow as described by S. Y. No and F. Ayazi in “The HARPSS Process for Fabrication of Nano-Precision Silicon Electromechanical Resonators”. IEEE Conf. on Nanotechnology, 10/28 30/01, (2001), pp. 489 494, and may be fabricated in combination with planar X/Y-axis gyroscopes, and tri-axial accelerometers as part of a six degree-of-freedom system. The process uses silicon-on-insulator (SOI) wafers with forty μm-thick of structural layer and two μm-thick buried oxide. Lateral trenches are etched via (DRIE) on the device layer utilizing a thermal-oxide mask in order to outline the resonator features and the surrounding electrodes, as illustrated in FIG. 11A. A 270 nm layer of sacrificial oxide is then grown to define the lateral (in-plane) capacitive gaps. Next, the trenches adjacent to the electrodes are re-filled with polysilicon; all other trenches are refilled with sacrificial TEOS. A second layer of sacrificial oxide (300 nm) is grown to define the out-of-plane capacitive gaps used for the planar gyros and accelerometers, as illustrated in FIG. 11B. This process is followed by the deposition and patterning of polysilicon that defines the vertical electrodes. The devices are then fully released in hydrofluoric acid (HF), as illustrated in FIG. 11C. Lastly, a capping wafer, which is processed independently, is bonded to the base wafer in order to provide hermetic wafer-level packaging (WLP) at a pressure level of 1 to 10 Torr, as illustrated in FIG. 11D. Through-silicon vias (TSVs) provide electrical connection from the device electrodes to the top of the cap wafer, and metal traces route the signals to pins at the edge of the die to facilitate wire-bonding with interface electronics.

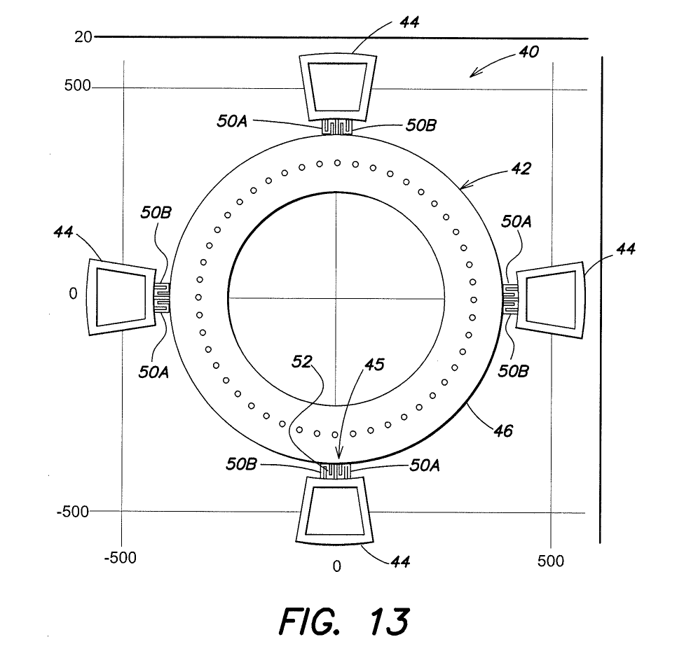

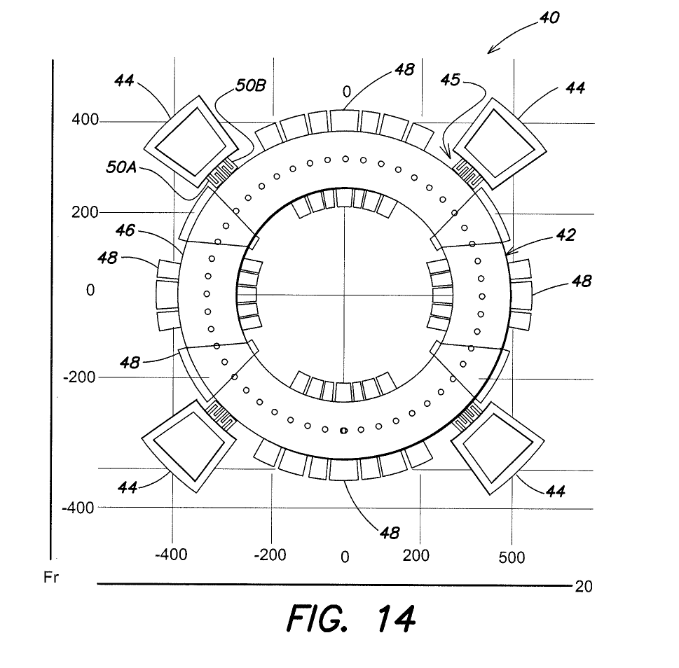

FIGS. 13 and 14 illustrate conceptually top views, of another embodiment of a decoupled resonant capacitive BAW gyroscope 40 comprising a decoupling mechanism 45 implemented with spring-like flexure members to effectively isolate and suspend a circular/oval shaped resonant element 42 of gyroscope 40 from support structures 44. In the disclosed embodiment, rather than the support structure comprising central anchor, the support structure 44 comprises a single annulus or a of plurality of structures disposed exterior of the resonant element 42 and coupled thereto at multiple locations along an exterior perimeter 46 of resonant element 42 by decoupling mechanism 45. In the illustrative embodiment, decoupling mechanism 45 comprises a plurality of spring-pair 50A-B constructed with a mirrored arrangement of substantially S-shaped springs 50A-B, each comprising a plurality of flexures 52. First ends of the springs 50A-B are typically connected radially along a perimeter wall of the resonant element 42. Second ends of the springs are connected to support structure(s) 44, which in the illustrative embodiment, maybe any of the plurality of support structures 44 located about an exterior perimeter of resonant element 42. Each flexure member 52 is characterized by at least on abrupt angular transition, typically a right angle, between the points at which it is coupled to either resonant element 42 or support structure 44. As illustrated in FIG. 13, in the illustrative embodiment, each flexure member 52 has four right angle transitions between the points or junctures at which it is coupled to either resonant element 42 or the support structure 44. In embodiments, flexure member 52 may have the same or different thickness than either resonant element 42 or support structure 44.

FIG. 14 illustrates the decoupled resonant capacitive BAW gyroscope 40 of electrodes FIG. 13 in conjunction with electrodes 48. Decoupling mechanism 45 has substantially the same effect on its resonant element 42 as decoupling member 15 has on its resonant element 12, respectively, namely to reduce the amount of energy transferred between the resonator element 42 and the support structure/substrate 44 and to cause the frequency of the out-of-plane modes of resonance to be in close-proximity to the frequency of the in-plane modes of resonance.

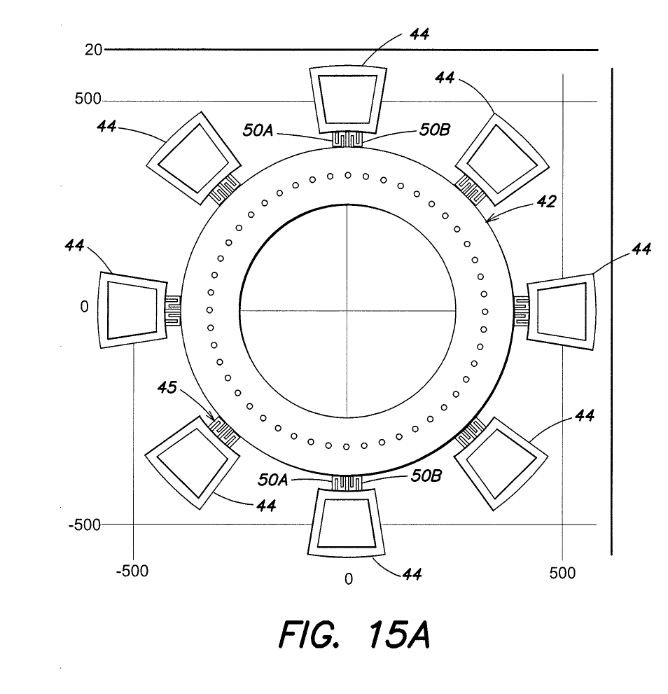

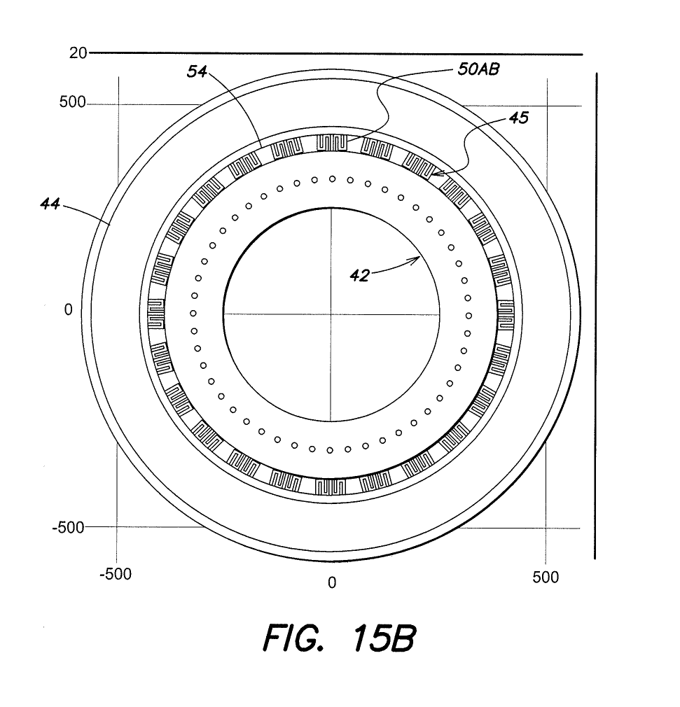

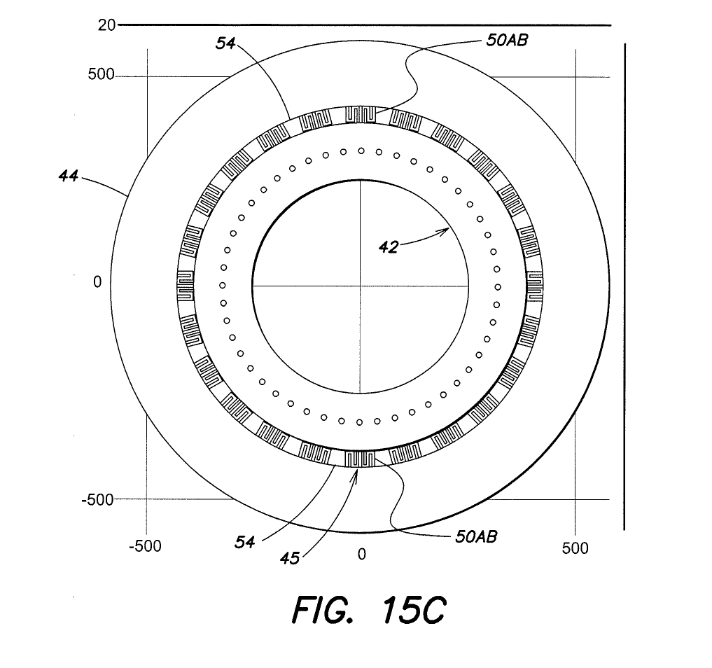

FIGS. 15A-C illustrate conceptually top views of additional embodiments of mechanism for decoupling the resonant element 42 from the support structure 44. The geometry and dimensions and number of the springs 50 may be designed in order to effectively reduce the amount of energy transferred between the resonator and the support/substrate and to cause the frequency of the out-of-plane modes of resonance to be in close-proximity to the frequency of the in-plane modes of resonance.

FIG. 15A illustrates conceptually a top view of an embodiment in which the decoupling mechanism 45 comprises eight spring-pairs 50A-B, similar to those illustrated in FIGS. 13-14, coupled to eight separate support structures 44.

FIG. 15A-B illustrate conceptually top views of an embodiment in which the decoupling mechanism 45 comprises twenty four spring-pairs 50A-B, similar to those illustrated in FIGS. 13-14, alternatingly arranged with projections 54 and extending between a circular annulus support structure 44 and resident element 42. In the illustrative embodiment springs 50 may be arranged adjacently in mirrored, i.e. symmetrically reflected, pairs

The reader will appreciate that a gyroscope apparatus designed and/or manufactured in accordance with the disclosure minimizes environmental dependencies—such as temperature, shock and vibration—through the reduction of anchor-loss.

It will be obvious to those recently skilled in the art that modifications to the apparatus and process disclosed here in may occur, including substitution of various component values or nodes of connection, without parting from the true spirit and scope of the disclosure. For example, even though results are for axis-symmetric mode-matched high-frequency gyroscopes, the methods and structures herein are applicable to any type of vibratory gyroscope.

What is claimed is:

1. The resonant apparatus comprising:
a resonant member;
a structure for supporting the resonant member relative to a another surface, and
a decoupling mechanism for flexibly decoupling the resonant member from the support structure.

2. The apparatus of claim 1 wherein the resonant member has is substantially annulus shaped.

3. The apparatus of claim 1 wherein the structure for supporting the resonant member comprises an anchor.

4. The apparatus of claim 3 wherein the anchor is coupled to a substrate.

5. The apparatus of claim 1 wherein the decoupling mechanism comprises a plurality of springs coupling a perimeter the resonant member to the supporting structure.

6. The apparatus of claim 5 wherein the plurality of springs are arranged in mirrored pairs about the perimeter the resonant member.

7. The apparatus of claim 5 wherein each of the springs comprises a flexure member having a first end coupled to the perimeter of the resonant member and a second end coupled the supporting structure.

8. The apparatus of claim 7 wherein the flexure member has at least one substantially right angle transition between the first end and the second end in an unflexed mode.

9. The apparatus of claim 7 wherein the flexure member has at least four substantially right angle transitions between the first end and the second end when in an unflexed mode.

10. The apparatus of claim 7 wherein the flexure member has at least eight substantially right angle transitions between the first end and the second end when in an unflexed mode.

11. The apparatus of claim 7 wherein the flexure member has at least twelve substantially right angle transitions between the first end and the second end when in an unflexed mode.

12. The apparatus of claim 1 wherein the decoupling mechanism enables degeneracy of in-plane resonance modes of the resonant member.

13. A gyroscope apparatus comprising:
a substantially annulus shaped resonator element having a pattern of flexure members extending outward therefrom; and
a structure for supporting the resonant member relative to a another surface, and
wherein each flexure member has a plurality of substantially right angle transitions between first and second ends thereof.

14. A method of manufacturing a bulk acoustic wave resonator element comprising:
A) forming an annulus shaped resonator element having a perimeter edge;
B) etching a plurality of apertures in the resonator element to collectively define a plurality of springs extending from the perimeter edge, wherein the springs each of the springs comprises a flexure member having a plurality of substantially right angle transitions.

15. An article of manufacture comprising an annulus shaped resonator element separated from a support structure by a plurality of springs connecting, wherein each of the springs comprises a flexure member having a plurality of substantially right angle transitions between junctures with the annulus shaped resonator element and support structure.

16. The article of manufacture of claim 15 wherein each of the support structure comprises a plurality of support structures disposed about an exterior perimeter of the annulus shaped resonator element.

17. The article of manufacture of claim 15 wherein support structure comprises an annulus shaped support structures disposed about an exterior perimeter of the annulus shaped resonator element.

18. The article of manufacture of claim 15 wherein support structure comprises a central anchor disposed within an interior perimeter of the annulus shaped resonator element, so that the resonator element is axis symmetric about the support structure.

19. The article of manufacture of claim 15 wherein the plurality of springs are arranged in mirrored pairs.
